(19) United States
(12) Patent Application Publication
(10) Pub. No.: US 2006/0243995 A1
(43) Pub. Date: Nov. 2, 2006

(54) WHITE LIGHT EMITTING DIODE DEVICE

(76) Inventors: Chi-Shain Hong, Taipei (TW); Chang-Ho Chen, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,694

(22) Filed: Sep. 20, 2005

(30) Foreign Application Priority Data
Apr. 29, 2005 (TW) 94113820

(51) Int. Cl. H01L 33/00

(52) U.S. Cl. 257/98; 257/100; 257/99; 257/E33.059; 257/E33.061

(57) ABSTRACT

A white light emitting diode device (white LED device) is provided. The white LED device includes an LED chip and a phosphor. A first light beam with wavelength between about 380 nm and about 450 nm is emitted from the LED chip. The phosphor is distributed in the range of the first light beam, wherein the phosphor is excited by the first light beam to emit a second light beam with wavelength between about 560 nm and about 580 nm. The first light beam and the second light beam are mixed to produce white light. The white LED device provides excellent light emitting efficiency and color rendering property, and has low manufacturing cost.

### CROSS-REFERENCE TO RELATED APPLICATION

This application claims the priority benefit of Taiwan application serial no. 94113820, filed on Apr. 29, 2005. All disclosure of the Taiwan application is incorporated herein by reference.

### BACKGROUND OF THE INVENTION

1. Field of Invention

The present invention relates to a light emitting diode device (an LED device). More particularly, the present invention relates to a white light emitting diode device (a white LED device) with excellent light emitting efficiency and color rendering property.

2. Description of Related Art

The Light Emitting Diode (LED) is a semiconductor device which can convert electric energy into light; that is, electric current is provided to the semiconductor compound to release the superfluous energy in the form of light through recombination of the electron and electronic hole, so as to achieve lighting effect.

As the light emitting from an LED device is cold lighting, instead of heat or discharge lighting, the LED device can live up to more than 100,000 hours, and no idling time is needed. In addition, the LED device has advantages such as quick response speed (about 10-9 second), small volume, power efficiency, low contamination (no mercury contained), high reliability and suitability for mass production, therefore the LED device can be applied widely in various fields.

The most remarkable is the white LED device. Especially in recent years, as the light emitting efficiency of the white LED device continues to improve, the white LED device can be applied in various fields, such as the light source of scanner, the back light source of liquid crystal display (LCD) or cell phone, or common lighting devices, and the white LED device has begun to substitute the conventional fluorescent lamp and incandescent lamp.

The conventional white LED devices can be divided into the following three types.

(1) The red LED chip, green LED chip and blue LED chip are used to produce red light, green light and blue light, and then the red light, green light and blue light are mixed to produce white light. This type of white LED device is a white LED device with three wavelengths. Although the light emitting efficiency of this method is high, the manufacturing cost is high because a plurality of single light LED chips are needed simultaneously.

(2) A blue LED chip is mixed with a yellow inorganic phosphor (or a yellow organic phosphor) to produce white light. Wherein, the blue LED chip emits the blue light with a wavelength between about 440 nm and about 490 nm. The yellow inorganic phosphor can emit yellow light when irradiated by blue light, and the yellow light and the original blue light are mixed to produce white light. This type of white LED device is easier to manufacture than the first white LED device, and also has lower manufacturing cost. However, as the light emitting efficiency of the type of white LED device is low, and this type of white LED device is of two wavelengths (only blue light and yellow light are mixed), its color rendering property and displayed color temperature are not as good as the white LED device with three wavelengths.

(3) The ultraviolet LED chip is mixed with red, green and blue phosphors to produce white light. The wavelength of the ultraviolet light is between 380 nm and 450 nm, and the various red, green and blue phosphors may emit red, green and blue light respectively when irradiated by ultraviolet light, and the red, green and blue lights are mixed to produce white light. However, compared with the aforementioned the second type of white LED device, the light emitting efficiency of the white LED device is lower.

In general, the ultraviolet LED chip is mixed with three color phosphors, and the overall light emitting efficiency is the multiplication of the light emitting efficiency of the three color phosphors. That is, if the light emitting efficiency of the red phosphor, green phosphor and blue phosphor is Er, Eg and Eb, respectively, the overall light emitting efficiency of the white LED device is [Er×Eg×Eb]. However, each light emitting efficiency is a factor less than 1, and the red light emitting efficiency Er is very low, so that the more types of phosphors are adopted, the lower the overall light emitting efficiency will be, which works against the overall light emitting efficiency.

### SUMMARY OF THE INVENTION

Accordingly, the present invention is directed to a white LED device, capable of providing excellent light emitting efficiency and color rendering property.

The present invention provides a white LED device. The white LED device includes an LED chip and a phosphor. A first light beam with a wavelength between about 380 nm and about 450 nm is emitted from the LED chip. The phosphor is distributed in the range of the first light beam, wherein the phosphor is excited by the first light beam to emit a second light beam with a wavelength between about 560 nm and about 580 nm. The first light beam and the second light beam are mixed to produce white light.

According to one embodiment of the present invention, the wavelength of the aforementioned second light beam is, for example, between about 550 nm and about 565 nm.

According to one embodiment of the present invention, the wavelength of the aforementioned second light beam is, for example, between about 505 nm and about 510 nm.

The white LED device according to one embodiment of the present invention further comprises a loading support, wherein the LED chip is configured on and electrically connected to the loading support. And, the loading support is, for example, a package support bracket or a package substrate.

The white LED device according to one embodiment of the present invention further comprises an encapsulant which is configured on the loading support and at least covers the LED chip. And, the phosphor is arranged within the encapsulant, and the material of the encapsulant is, for example, epoxy resin.

The material of the aforementioned phosphor in one embodiment of the present invention includes, for example, ZnSe or ZnS.

The present invention further provides a white LED device, including an LED chip, a first phosphor and a second phosphor. A first light beam with a wavelength between about 380 nm and about 450 nm is emitted from the LED chip. The first phosphor is distributed in the range of the first light beam, wherein the first phosphor is excited by the first light beam to emit a second light beam with a wavelength between about 520 nm and about 570 nm. The second phosphor is distributed in the range of the first light beam, wherein the second phosphor is excited by the first light beam to emit a third light beam with a wavelength between about 570 nm and about 650 nm. The first light beam, the second light beam and the third light beam are mixed to produce white light.

According to one embodiment of the present invention, the wavelength of the aforementioned second light beam is between about 550 nm and about 565 nm, and the wavelength of the aforementioned third light beam is between about 580 nm and about 600 nm.

According to one embodiment of the present invention, the wavelength of the aforementioned second light beam is between about 505 nm and about 510 nm, and the wavelength of the aforementioned third light beam is between about 630 nm and about 645 nm.

The white LED device according to one embodiment of the present invention further comprises a loading support, wherein an LED chip is configured on and electrically connected to the loading support. And, the loading support may be, for example, a package support bracket or a package substrate.

The white LED device according to one embodiment of the present invention further comprises an encapsulant which is configured on the loading support and at least covers the LED chip. And, the first and second phosphors are arranged within the encapsulant, and the material of the encapsulant is, for example, epoxy resin.

The material of the aforementioned first and second phosphors according to one embodiment of the present invention includes, for example, ZnSe or ZnS.

As the present invention adopts an ultraviolet LED chip (with a wavelength between about 380 nm and about 450 nm) and single color phosphor (with a wavelength between about 560 nm and about 580 nm) or dual color phosphors (with a wavelength between about 520 nm and about 570 nm, and a wavelength between about 570 nm and about 650 nm) to mix to produce white light. Since at least one phosphor is reduced compared with the white LED device with ultraviolet light LED chip mixing with more than three phosphors, the overall emitting light efficiency can be improved, and the brightness of the white light is also improved.

In order to the make the aforementioned and other objects, features and advantages of the present invention comprehensible, a preferred embodiment accompanied with figures is described in detail below.

### BRIEF DESCRIPTION OF THE DRAWINGS

FIG. 1 is a schematic diagram of a white LED device according to one embodiment of the present invention.

FIG. 2 is a chromaticity diagram for selecting the wavelength of a second light beam according to one embodiment of the present invention.

FIG. 3 is a schematic diagram showing the sensitivity of human eye to light beam.

FIG. 4 is a schematic diagram of the color matching range according to one embodiment of the present invention.

FIG. 5A is a schematic diagram of the white LED device with package support bracket.

FIG. 5B is a partially enlarged schematic diagram of the white LED device in FIG. 5A.

FIG. 6 is a schematic diagram of a white LED device of another embodiment of the present invention.

FIG. 7 is the chromaticity diagram for selecting the wavelength of the second light beam and the third light beam according to one embodiment of the present invention.

FIGS. 8A and 8B are schematic diagrams of the color matching range according to one embodiment of the present invention.

### DESCRIPTION OF EMBODIMENTS

### The First Embodiment

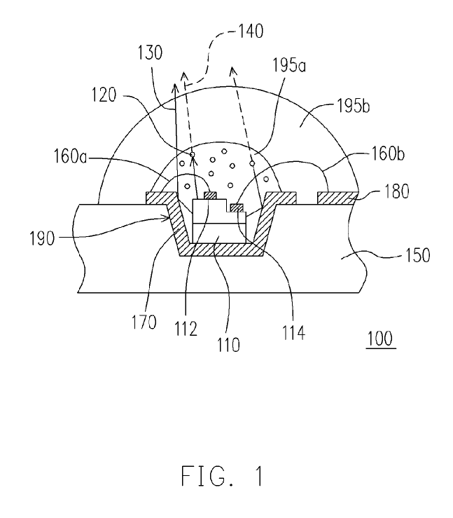

FIG. 1 is a schematic diagram of a white LED device according to one embodiment of the present invention. Please refer to FIG. 1. The white LED device 100 includes, for example, an LED chip 110 and a phosphor 120. A first light beam 130 with a wavelength between about 380 nm and about 450 nm is emitted from the LED chip 110. The phosphor 120 is distributed in the range of the first light beam 130, wherein the phosphor 120 is excited by the first light beam 130 to emit a second light beam 140 with a wavelength between about 560 nm and about 580 nm. The first light beam 130 and the second light beam 140 are mixed to produce white light.

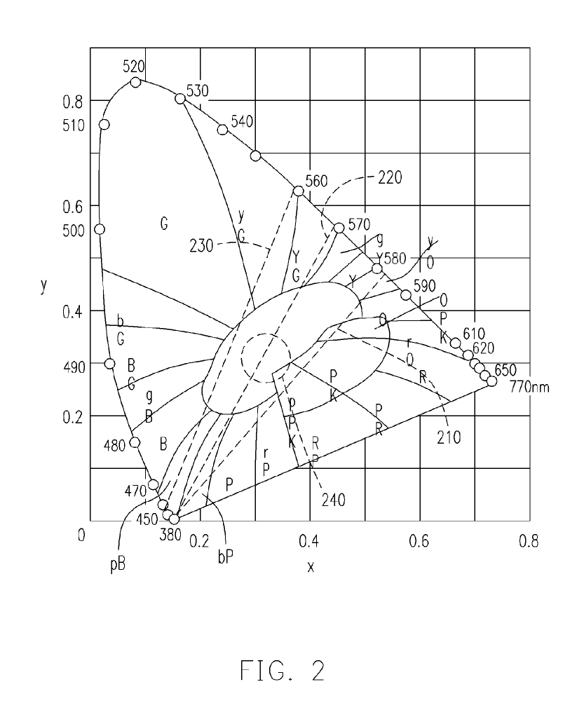

FIG. 2 is a chromaticity diagram for selecting the wavelength of a second light beam according to one embodiment of the present invention. Please refer to FIG. 2. Since a first light beam 130 with a wavelength between about 380 nm and about 450 nm is emitted from the white LED device 100, so three dotted lines 210, 220 and 230 can be drawn from the wavelength of about 380 nm to 450 nm to cover the pure white light range 240 (i.e., the dotted circle range), and further to obtain the wavelength of the desired contrast color, i.e. a second light beam 140 with a wavelength between about 560 nm and about 580 nm. Therefore, the phosphor with a wavelength between about 560 nm and about 580 nm is selected to mix a first light beam 130 and a second light beam 140 to produce the white light. Note that the wavelength of the second light beam 140 is selected in the present invention in consideration of the sensitivity of human eye to light beam, so that better color rendering property can be obtained.

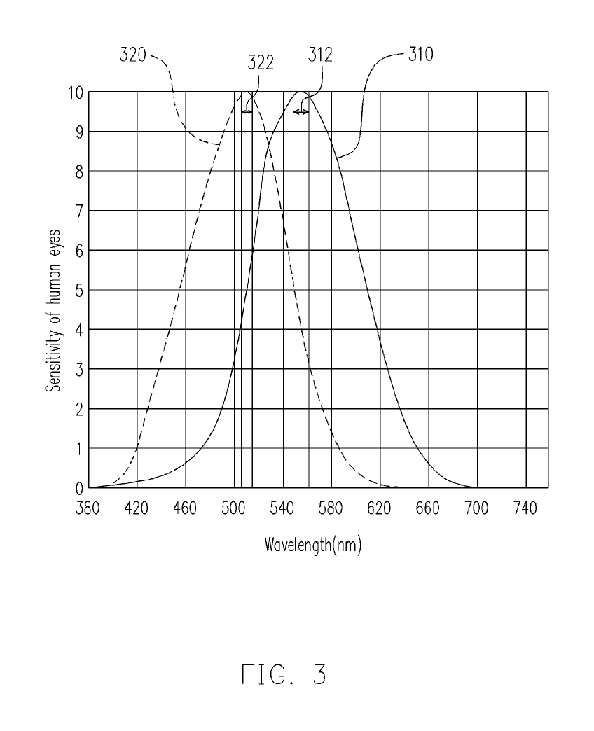

FIG. 3 is a schematic diagram of the sensitivity of human eye to light beam. Please refer to FIG. 3. The curve 310 represents the sensitivity of human eye to light beam in daytime. It can be learned from the curve 310 that the wavelength to which human eyes have preferred sensitivity in daytime is of the range 312 between about 550 nm and about 565 nm. In addition, the curve 320 represents the sensitivity of human eye to light beam at night. It can be learned from the curve 320 that the wavelength to which human eyes have preferred sensitivity at night is of the range 322 between about 505 nm and about 510 nm.

As shown in FIG. 2, the wavelength of the second light beam 140 itself should be between about 560 nm and 580 nm, and considering the preferred light beam sensitivity of human eyes, in one embodiment of the present invention, a second light beam 140 with a wavelength between about 550 nm and about 565 nm at daytime can be selected, so that human eyes may have preferred sensitivity to the produced white light beam, and further the preferred color rendering property can be obtained. While at night, a second light beam 140 with a wavelength between about 505 nm and about 510 nm can be selected, so that human eyes may have preferred sensitivity to the produced white light beam, and the preferred color rendering property can be obtained.

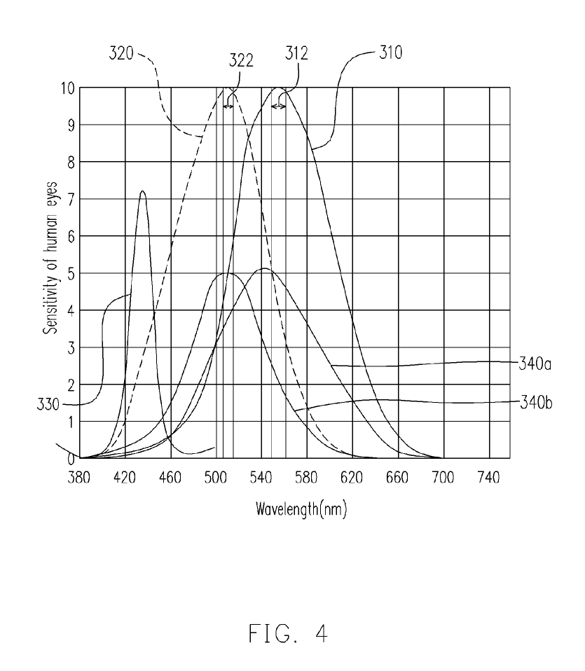

As aforementioned, FIG. 4 is a schematic diagram of the color matching range according to one embodiment of the present invention. Please refer to FIG. 4. The curve 330 represents the wavelength between about 380 nm and about 450 nm emitted from the LED chip 110. And, for the range 312 to which human eyes have high light sensitivity in daytime as shown in the curve 310, a phosphor (as shown in curve 340a) which can emit light with a wavelength between 550 nm and about 565 nm can be selected, so as to improve human eyes' sensitivity to light beam, and further the desired color rendering property can be obtained. While at night, a phosphor (as shown in curve 340b) which can emit light with a wavelength between about 505 nm and about 510 nm can be selected, so as to improve human eyes' sensitivity to the produced white light beam, and further the desired color rendering property can be obtained.

Moreover, please refer to FIG. 1. According to an embodiment of the present invention, the white LED device 100, for example, further includes a loading support 150, and an LED chip 110 is configured on and electrically connected to the loading support 150. According to one embodiment of the present invention, the LED chip 110 can be electrically connected to the loading support 150 by wire bonding or flip chip bonding.

As shown in FIG. 1, the LED chip 110, for example, is electronically connected to the loading support 150 by wire bonding. Wherein, the LED chip 110, for example, has contact pad 112 and contact pad 114, while the contact pad 112 is electrically connected to a conductive layer 170 by bonding wire 160a, and the contact pad 114 is electrically connected to another conductive layer 180 by bonding wire 160b. In addition, the flip chip bonding technology is to form the conductive protruding block (not shown) at the bottom of the LED chip 110, then the LED chip 110 is electrically connected to the loading support 150 by the conductive protruding block.

According to one embodiment of the present invention, as shown in FIG. 1, the loading support 150 is a package substrate, and the package substrate, for example, has a concavity 190, and the conductive layer 170 is paved on the surface of the concavity 190. Therefore, the first light beam 130 emitted from the LED chip 110 disposed within the concavity 190 can be reflected by the conductive layer 170 paved on the concavity 190, so as to improve the efficiency of the first light beam 130.

Please again refer to FIG. 1. The white LED device 100 according to one embodiment of the present invention further includes an encapsulant 195a which is configured on the loading support 150 and at least covers the LED chip 110, and the phosphor 120 is arranged within the encapsulant 195a. More in detail, the phosphor 120 is mixed with a small part of the encapsulant 195a, then coated around the LED chip 110. Then, the entire white LED device 100 is encapsulated by the remaining encapsulant 195b that has not mixed with the phosphor 120, in order to avoid the moisture invasion, so to elongate the life of the white LED device 100. According to one embodiment of the present invention, the material of the encapsulant 195a, 195b is, for example, epoxy resin. And the aforementioned material of the phosphor 120 is, for example, ZnSe or ZnS, which is suitable to be excited by the first light beam 130 to emit the second light beam 140 with a wavelength between about 560 nm and about 580 nm.

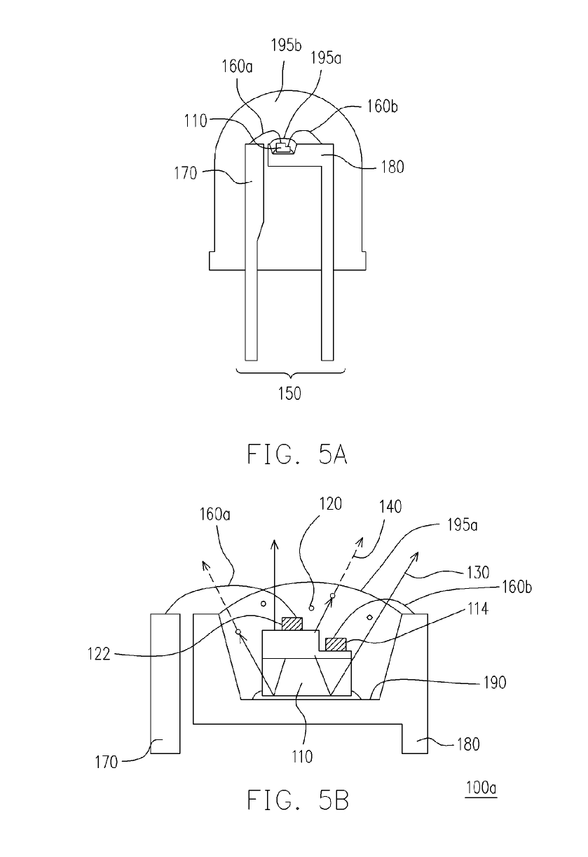

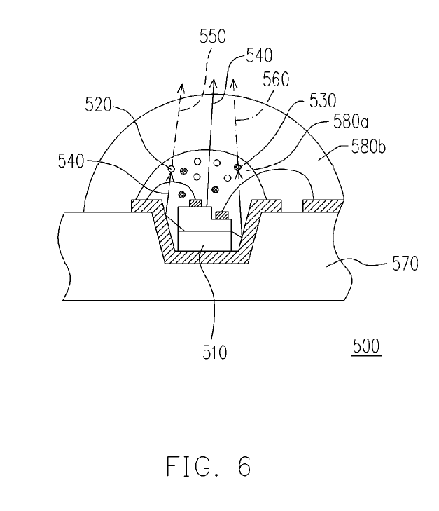

Moreover, according to one embodiment of the present invention, the loading support 150 can also be, for example, a package support bracket. FIG. 5A is a schematic diagram of the white LED device with package support bracket, and FIG. 5B is a partially enlarged schematic diagram of the white LED device in FIG. 5A. Please refer to FIGS. 5A and 5B. The related members of the loading support 150 of the white LED device 100a are similar or the same as those of the loading support 150 of the white LED device 100 as shown in FIG. 1, therefore they are omitted herein.

In summary, the white light with excellent light emitting efficiency can be obtained by mixing the ultraviolet LED chip (with a wavelength between about 380 nm and 450 nm) and single color phosphor (with a wavelength between about 560 nm and 580 nm).

### The Second Embodiment

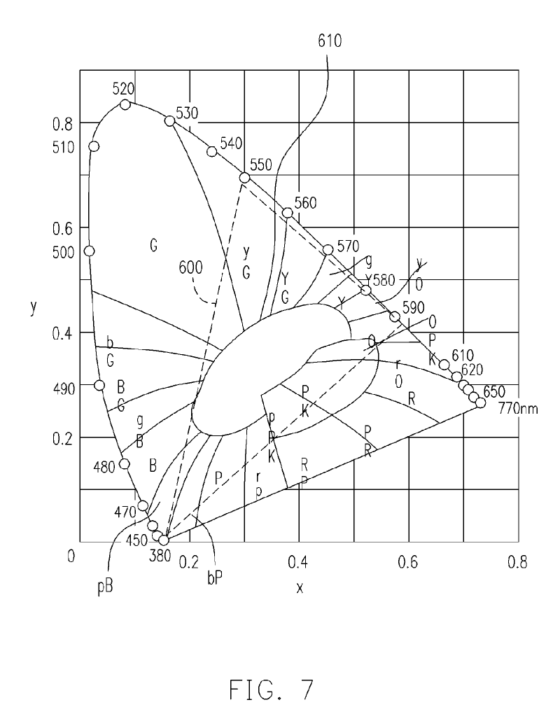

FIG. 6 is a schematic diagram of a white LED device according to another embodiment of the present invention. Please refer to FIG. 6. The white LED device 500 includes, for example, an LED chip 510, a first phosphor 520 and a second phosphor 530.

As shown in FIG. 6, a first light beam 540 with a wavelength between about 380 nm and about 450 nm is emitted from the LED chip 510. The first phosphor 520 is distributed in the range of the first light beam 540, wherein the first phosphor 520 is excited by the first light beam 540 to emit a second light beam 550 with a wavelength between about 520 nm and about 570 nm. The second phosphor 530 is distributed in the range of the first light beam 540, wherein the second phosphor 530 is excited by the first light beam 540 to emit a third light beam 560 with a wavelength between about 570 nm and about 650 nm. The white LED device 500 can produce white light by mixing the first light beam 540, the second light beam 550 and the third light beam 560.

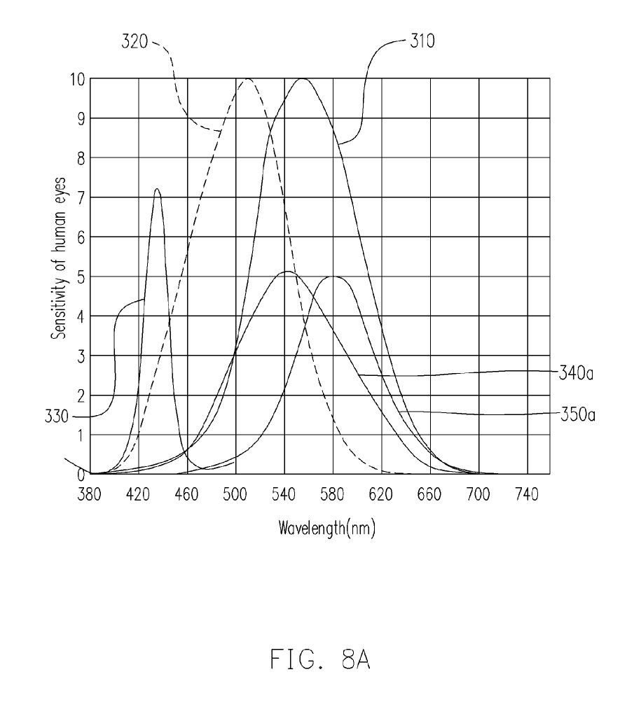

FIG. 7 is a chromaticity diagram for selecting the wavelength of the second light beam and the third light beam according to one embodiment of the present invention. Please refer to FIG. 7. As the wavelength of the first light beam 540 emitted from the white LED device 500 is between about 380 nm and about 450 nm, a triangle 600 can be drawn from the wavelength of 380 nm to 450 nm to cover the pure white light range 610 (i.e. the circle range), and further the wavelengths of the two contrast colors can be obtained. That is, the second light beam 550 with a wavelength between about 520 nm and about 570 nm, and the third light beam 560 with a wavelength between about 570 nm and 650 nm can be selected.

In other words, a first phosphor 520 which can emit a second light beam 550 with a wavelength between about 520 nm and about 570 nm and a second phosphor 530 which can emit a third light beam 560 with a wavelength between about 570 nm and about 650 nm can be selected to have the first light beam 540, the second light beam 550 and the third light beam 560 mixed to produce white light.

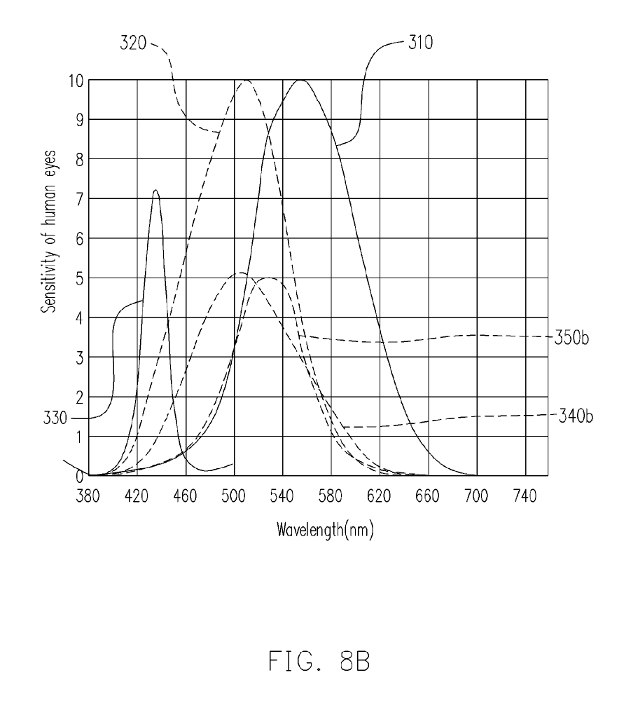

Also, the present invention considers the different sensitivity of human eyes to light beam in daytime and at night to select the best wavelength of the light beam emitted from the excited first phosphor 520 and the second phosphor 530. FIGS. 8A and 8B are schematic diagrams of the color matching range according to one embodiment of the present invention.

Please refer to FIG. 8A. FIG. 8A is the schematic diagram of the high daytime sensitivity curves 340a and 350a of human eyes to the light beam emitted from the first phosphor 520 and the second phosphor 530. It can be learned from FIG. 8A that in daytime, the first phosphor 520 (i.e. as shown in the curve 340a) which can emit a second light beam 550 with a wavelength between about 550 nm and 565 nm and the second phosphor 530 (i.e. as shown in the curve 350a) which can emit a third light beam 560 with a wavelength between about 580 nm and 600 nm can be selected, so as to obtain the white light with excellent light emitting efficiency, and also to improve the color rendering property of the produced white light.

Then please refer to FIG. 8B. FIG. 8B is the schematic diagram of the high night time sensitivity curves 340b and 350b of human eyes to the light beam emitted from the first phosphor 520 and the second phosphor 530. As shown in FIG. 8B, at night, the first phosphor 520 (i.e. as shown in the curve 340b) which can emit a second light beam 550 with a wavelength between about 505 nm and 510 nm and the second phosphor 530 (i.e. as shown in the curve 350b) which can emit a third light beam 560 with a wavelength between about 630 nm and 645 nm can be selected, so as to obtain the white light with excellent light emitting efficiency, and also to improve the color rendering property of the produced white light.

Please again refer to FIG. 6. According to one embodiment of the present invention, the white LED device 500, for example, further includes a loading support 570, and an LED chip 510 is configured on and electrically connected to the loading support 570. The loading support 570 may be a package substrate or a package support bracket, and the loading support 570 is electrically connected to the LED chip 510 by, for example, wire bonding or flip chip bonding. The detail members of the white LED device 500 are the same or similar with those of the white LED device 100 described in the first embodiment, therefore they are omitted herein.

Note that, according to one embodiment of the present invention, the white LED device 500 further includes an encapsulant 580a which is provided on the loading support 570 and at least covers the LED chip 510. And, the first phosphor 520 and the second phosphor 530 are arranged within the encapsulant 580a. More in detail, the first phosphor 520 and the second phosphor 530 may first mix with a small part of the encapsulant 580a, then coated around the LED chip 510. Then, the entire white LED device 500 is encapsulated by the encapsulant 580b that is not mixed with the first phosphor 520 and the second phosphor 530. According to one embodiment of the present invention, the material of the encapsulant 580a, 580b is, for example, epoxy resin. And the material of the first phosphor 520 and the second phosphor 530 is, for example, ZnSe or ZnS, which is suitable to be excited by the first light beam 540 to emit the second light beam 550 and the third light beam 560, respectively. Therefore, the white light with excellent light emitting efficiency can be obtained by mixing the ultraviolet LED chip (with wavelength between about 380 nm and 450 nm) and dual color phosphors (with wavelength between about 520 nm and 570 nm, and wavelength between about 570 nm and 650 nm).

In summary, the white LED device of the present invention has the following advantages:

The present invention adopts an ultraviolet LED chip and single color phosphor or dual color phosphors to mix and produce white light, instead of more than three phosphors.

The present invention considers the different sensitivity of human eyes to light beam in daytime and at night, and selects the single phosphor or dual phosphors which can emit light wavelength with higher sensitivity to improve the color rendering property of the white color.

The present invention can reduce the use of phosphor, so the manufacturing cost of the white LED device can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A white LED device, comprising:
an LED chip, adapted to emit a first light beam with wavelength between about 380 nm and about 450 nm; and
a phosphor, distributed in the range of the first light beam, wherein the phosphor is excited by the first light beam to emit a second light beam with wavelength between about 560 nm and about 580 nm, and the first light beam and the second light bean are mixed to produce white light.

2. The white LED device as claimed in claim 1, wherein the wavelength of the second light beam is between about 550 nm and about 565 nm.

3. The white LED device as claimed in claim 1, wherein the wavelength of the second light beam is between about 505 nm and about 510 nm.

4. The white LED device as claimed in claim 1, wherein the white LED device further comprises a loading support, and the LED chip is configured on and electrically connected to the loading support.

5. The white LED device as claimed in claim 4, wherein the loading support comprises a package support bracket or a package substrate.

6. The white LED device as claimed in claim 1, wherein the white LED device further comprises an encapsulant configured on the loading support and at least covers the LED chip, and the phosphor is arranged within the encapsulant.

7. The white LED device as claimed in claim 6, wherein the material of the encapsulant includes epoxy resin.

8. The white LED device as claimed in claim 1, wherein the material of the phosphor includes ZnSe or ZnS.

9-16. (canceled)
